(19) United States
(12) Patent Application Publication
(10) Pub. No.: US 2009/0230527 A1
(43) Pub. Date: Sep. 17, 2009

(54) Multi-chips package structure and the method thereof

(76) Inventor: Geng-Shin SHEN, Hsinchu City (TW)

Correspondence Address: SINORICA, LLC, 2275 Research Blvd., Suite 500, ROCKVILLE, MD, 20850, US

(21) Appl. No.: 12/325,324

(22) Filed: Dec. 1, 2008

(30) Foreign Application Priority Data
Mar. 13, 2008 (TW) 097108815

(51) Int. Cl. H01L 23/495; H01L 21/56

(52) U.S. Cl. 257/676; 438/112; 257/E21.502; 257/E23.04

(57) ABSTRACT

A multi-chips package structure is provided, which includes a chip-placed frame having a plurality of chip-placed areas thereon, and two adjacent chip-placed areas is connected by a plurality of leads; a plurality of chips, each chip has a plurality of pads on an active surface thereon, and is provided on the chip-placed area; a package body is covered around the four sides of the chip-placed frame, and the pads of the chip is to be exposed; one end of a plurality of patterned metal traces is electrically connected to the plurality of pads, another end is extended to cover the surface of the patterned first protection layer; a patterned second protective layer is covered on the patterned metal traces and another end of the patterned metal traces is to be exposed; a plurality of patterned UMB layer is formed on the extended surface of the patterned metal traces; and a plurality of conductive elements is formed on the patterned UMB layer and is electrically connected to one end of the exposed portion of the patterned metal traces.

### BACKGROUND OF THE INVENTION

1. Field of the Invention

The present invention is relates to a multi-chips package method, and more particularly is related to a package method by utilizing a chip-placed frame to relocate the chips.

2. Description of the Prior Art

The semiconductor technology is well developed and grown up very fast. Because the microlized semiconductor dice are required to include more functions, the semiconductor dice are necessary to have more input/output (I/O) pads. The density of the metal pins is higher day after day. Therefore, the previous lead package technology is not compatible for dice with high density of metal pins. A Ball Grid Array (BGA) package method is used for dices with high density of metal pins. The BGA package method is not only suitable for using in dices with high density of metal pins, but also the solder balls is not easy to be damaged and out of shape.

Because the 3C products, such as cell phone, personal digital assistant (PDA), or MP3 player, are more and more popular in the market, there are more and more complicated chips installed in a very tiny space. In order to solve the microlized problems, a wafer lever package (WLP) technology is developed. The WLP technology is able to package the dice before sawing them to be several chips. U.S. Pat. No. 5,323,051 discloses a WLP technology. However, when the pads on the active surface of the chips are increased and the interval between the pads is become smaller, the WLP technology will cause the signal overlapped or interrupted problems. So, when the chip is become further smaller, the previous package methods are not good enough to use.

In order to solve the problem described above, U.S. Pat. No. 7,196,408 discloses that a wafer is tested and sawed in semiconductor manufacture and put the good dice in another carrier board to do the package process. Therefore, the pads on the dice are able to be separated with good interval. For example a fan out technology is used, it is able to solve the small interval problem but it may cause the signal overlapped or signal interrupt problems.

Nevertheless, in order to let the semiconductor chips have smaller and thinner package structures, before sawing the dices, the wafer will do a thin process first, such as backside lapping process to thin the wafer in 2˜20 mils, and the wafer is sawed to be several pieces of chips. After the thin process is done, the dices are put on another carrier board and a molding process is used to encapsulate the chip to be a package structure. Because the chip is very thin, the package structure is also very thin. Therefore, when the package structure is left from the carrier board, the package structure would be out of shape and it would cause the difficulty to do the sawing process.

After sawing the wafer, because the dice are put on another carrier board, the size of the new carrier board is larger than the original carrier board, the ball mounting process is hard for the solder ball to be installed at the exact location and the reliability of the package structure is reduced.

Besides, in the package procedure, the manufacture equipment will generate more pressure in the dice during the ball mounting process. Because of the material of the balls, the resistance between the balls and the solder pads will be become higher than usual and it would affect the function of the chips.

### SUMMARY OF THE INVENTION

According to the problems described above, a multi-chips package structures and method is disclosed herein to relocate the chips and then do the package procedures.

Another object of the present invention is to provide a multi-chips package method to relocate the chips with different sizes on a carrier board.

Besides, one another object of the present invention is to provide a multi-chips package method to let the chips sawed from a 12 inches wafer put a chip-placed frame. Therefore, the 8 inches wafer package equipment is still useful and reduce the cost to buy some 12 inches package equipments.

One other object of the present invention is to provide multi-chips package method to package the chips, which are known as good chips, and the package material can be saved and the cost of the manufacture can be decreased.

Other project of the present invention is to relocate the chips by the chip-placed areas of the chip-placed frame and the accuracy of the relocation position of the chips is enhanced by the reference position of the chip-placed areas.

According to the objects described above, a multi-chips package method is disclosed and includes the following steps: providing a chip-placed frame, which includes a plurality of chip-placed area, and a plurality of leads are used to connect each of the chip-placed areas and there is a gap existed between the chip-placed areas; providing a wafer, and the wafer includes a top surface and a reverse surface and the wafer includes a plurality of chips and each of the chips includes an active surface and there are a plurality of pads disposed on the active surface; sawing the wafer to become the chips; disposing the chips on each of the chip-placed areas and a reverse surface of each of the chips is stuck on each of the chip-placed areas; pick and placing a carrier board with a adhesive layer on the active surface; injecting a polymer and the polymer material is disposed on a surface of the chip-placed area, and the polymer material is filled into the gaps and covering each of the chips to form a package structure; removing the adhesive layer and the carrier board to expose the active surface of each of the chips; forming a plurality of patterned first protective layer on the chips and exposing the pads on the active surface of each of the chips; forming a plurality of fan-out and patterned metal traces, and each of the patterned metal traces is electrically connected to the plurality of pads on the active surface of each of the chips, and each of the patterned metal traces includes a fan-out structure, which is extended out of the active surface of the chips; forming a patterned second protective layer to cover the patterned metal trace and expose a portion of the fan-out structure, which is extended out of the active surface of the chips; forming a plurality of patterned UBM layers to cover a portion of the fan-out structure, which is extended out of the active surface of the chips, and the patterned UBM layer is electrically connected to the patterned metal traces; forming a plurality of conductive elements, and the conductive elements are electrically connected to patterned metal traces by the patterned UBM layer; and sawing the package structure and the leads of the chip-placed frame to form a plurality of stand alone and packaged chips.

According to the objects described above, a multi-chips package method is disclosed herein and includes the following steps: providing a chip-placed frame, which includes a plurality of chip-placed area, and a plurality of leads are used to connect each of the chip-placed areas and there is a gap existed between the chip-placed areas; providing a wafer, and the wafer includes a top surface and a reverse surface and the wafer includes a plurality of chips and each of the chips includes an active surface and there are a plurality of pads disposed on the active surface; sawing the wafer to become the chips; disposing the chips on each of the chip-placed areas and a reverse surface of each of the chips is stuck on each of the chip-placed areas; pick and placing a carrier board with a adhesive layer on the active surface; injecting a polymer material and the polymer is disposed on a surface of the chip-placed area, and the polymer material is filled into the gaps and covering each of the chip-placed frame to form a package structure; removing the adhesive layer and the carrier board to expose the active surface of each of the chips; forming a plurality of patterned first protective layer on the chips and exposing the pads on the active surface of each of the chips; forming a plurality of fan-out and patterned metal traces, and each of the patterned metal traces is electrically connected to the pads on the active surface of each of the chips, and each of the patterned metal traces includes a fan-out structure, which is extended out of the active surface of the plurality of chips and the fan-out structure covers on a portion of the patterned first protective layer; forming a patterned second protective layer to cover the patterned metal traces and expose a portion of the patterned fan-out structure, which is extended out of the active surface of the chips; forming a plurality of patterned UBM layers to cover a portion of the fan-out structure, which is extended out of the active surface of the chips, and the patterned UBM layer is electrically connected to the patterned metal traces; forming a plurality of conductive elements, and the conductive elements are electrically connected to the patterned metal traces by the patterned UBM layer; and sawing the package structure and the leads of the chip-placed frame to form a plurality of stand alone and packaged chips.

According to the multi-chips package method, a multi-chips package structure is disclosed and includes a chip-placed frame, a chip, a package structure, a plurality of patterned first protective layer, a plurality of patterned metal traces, a plurality of second protective layer, a plurality of patterned UBM layer, and a plurality of conductive elements. The chip-placed frame includes a chip-placed area, and a top surface of the chip-placed area includes an adherent layer. The chip includes an active layer and a reverse surface, and the active layer includes a plurality of pads and the reverse surface is formed on the adherent layer of the chip-placed area. The package structure surrounding the chip-placed frame and the chip and the pads on active surface are exposed. The patterned first protective layers are used to cover the active surface of the chip and exposed the pads on the chips. One end of the patterned metal trace is electrically connected to the pads and one another end of the patterned metal trace is extended and covered a surface of the patterned first protective layer. The second protective layer is used to cover the patterned metal traces and expose a portion of a surface of a fan-out structure of the patterned metal traces, which is extended out of the active surface. The patterned UBM layers formed on the fan-out structure and electrically connected to the patterned metal traces. The conductive elements are formed on the patterned UBM layer and electrically connected to the patterned metal traces by the patterned UBM layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a view illustrating that a plurality of chips disposed on a wafer according to an embodiment of the present invention;

FIG. 2A and FIG. 2B are views illustrating that a chip-placed frame includes a plurality of chip-placed areas according to an embodiment of the present invention;

FIG. 3A and FIG. 3B are views illustrating that the wafer is sawed to form a plurality of chips and the chips are relocated on the chip-placed frame according to an embodiment of the present invention;

FIG. 4 is a sectional view illustrating that the chip-placed frame including a plurality of chips in AA segment of FIG. 3A or FIG. 3B;

FIG. 5 and FIG. 6 are steps' views illustrating that the carrier board including an adherent layer is stuck on the active surface of each of the chips according to an embodiment of the present invention;

FIG. 7 is a view illustrating that a polymer is formed on the chips according to an embodiment of the present invention;

FIG. 8 is a view illustrating that the polymer is flatted according to an embodiment of the present invention;

FIG. 9 is a view illustrating that the carrier board with adherent layer is removed to expose the active surface of each of the chips according to an embodiment of the present invention;

FIG. 10 is a view illustrating that a first protective layer is formed to cover the active surface of each of the chips and a portion of the polymer according to an embodiment of the present invention;

FIG. 11 is a view illustrating that a protective layer is formed on the chips to expose a plurality of pads according to an embodiment of the present invention;

FIG. 12 is a view illustrating that a patterned metal trace is formed to cover a plurality of pads according to an embodiment of the present invention;

FIG. 13 is a view illustrating that a protective layer is formed on the fan-out and patterned metal trace according to an embodiment of the present invention;

FIG. 14 is a view illustrating that a portion of the protective layer is removed to expose a plurality of pads according to an embodiment of the present invention;

FIG. 15 is a view illustrating that an UBM layer is formed after exposing a plurality of patterned metal traces a plurality of pads according to an embodiment of the present invention;

FIG. 16 is a view illustrating that a plurality of patterned UBM layer are formed on the surface of the patterned metal traces according to an embodiment of the present invention;

FIG. 17 is a view illustrating that a conductive element is formed on surface of each of the patterned UBM layer according to an embodiment of the present invention; and

FIG. 18 is a view illustrating that a package structure of a single chip according to an embodiment of the present invention.

### DESCRIPTION OF THE PREFERRED EMBODIMENT

In the present semiconductor package procedure, the wafer had passed in the front end process needs to do a thinning process first, such as the thickness of the wafer is thinned to 2˜20 mil thick. Then, a sawing process is used to cut the wafer to be several pieces of dice 110 and a means for pick and place is used to put those dice 110 to another carrier board. Obviously, because the interval between the dice on the carrier board is larger than the size of dice, those relocated dice is able to have larger interval. Therefore, the pads on the dice are able to be appropriately distributed.

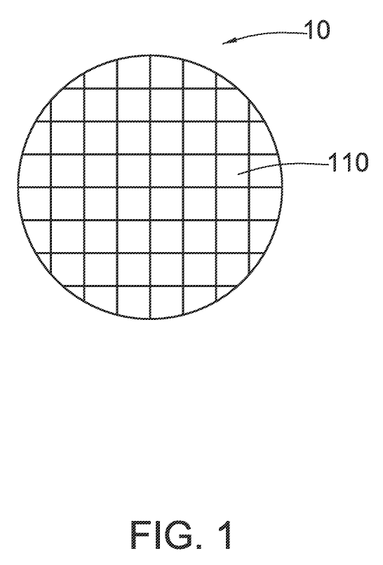

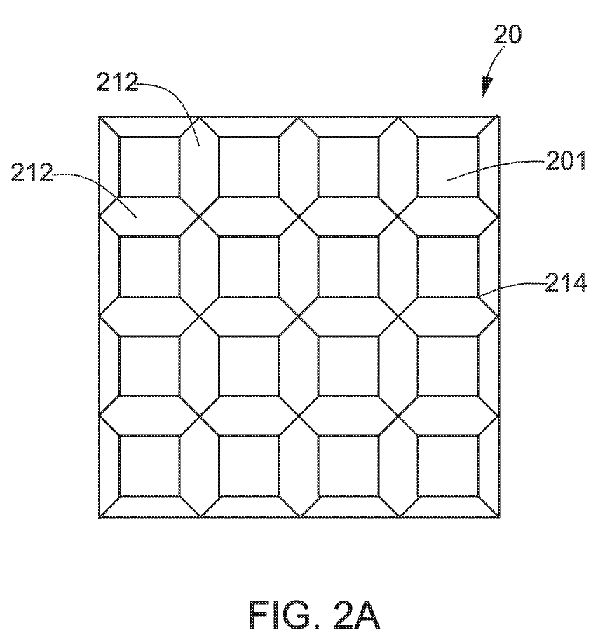

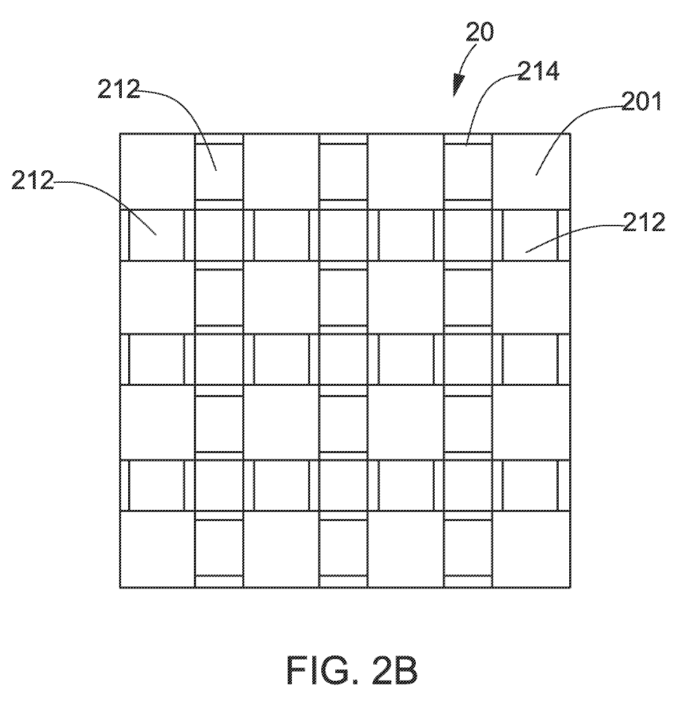

First, FIG. 1 is a top view showing that there is a plurality of dice 110 in a wafer 10 and each of the dice 110 includes several pads (not shown). FIGS. 2A and 2B are views showing that a chip-placed frame is used to relocate those chips. The chip-placed frame 20 is a reticulated frame and includes a plurality of chip-placed areas 210 with the same size. A plurality of leads 214 are used to connect each of the chip-placed areas 210. The connective way is to connect the four corners of the chip-placed area 210 and the four corners of the other chip-placed area 210 by the leads 214. Therefore, the adjacent chip-placed areas 210 are able to connect to each other and there is a gap between the adjacent chip-placed areas 210, as the rectangular gap 212 shown in FIG. 2A or FIG. 2B. The shape of the rectangular gap 212 can be like a diamond or a square and it is not limited in the embodiments of the present invention. The formation of the chip-placed areas 210 of the chip-placed frame 20 is providing a metal board, such as steal, copper or copper alloy, and removing a portion of metal by the way of etching and forming a plurality of chip-placed areas 210. The leads 214 are used to connect each of the chip-placed areas 210 and the connective method can be an interlaced method and the chip-placed areas 210 of the chip-placed frame 20 are arranged by a rectangular.

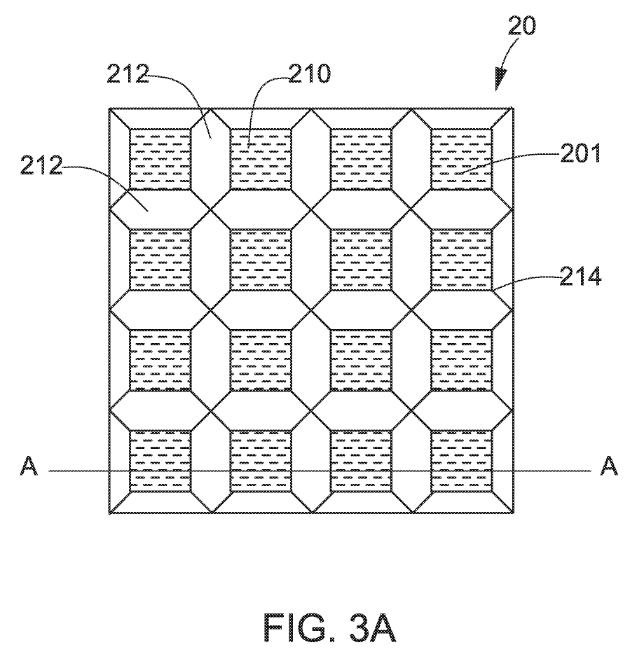

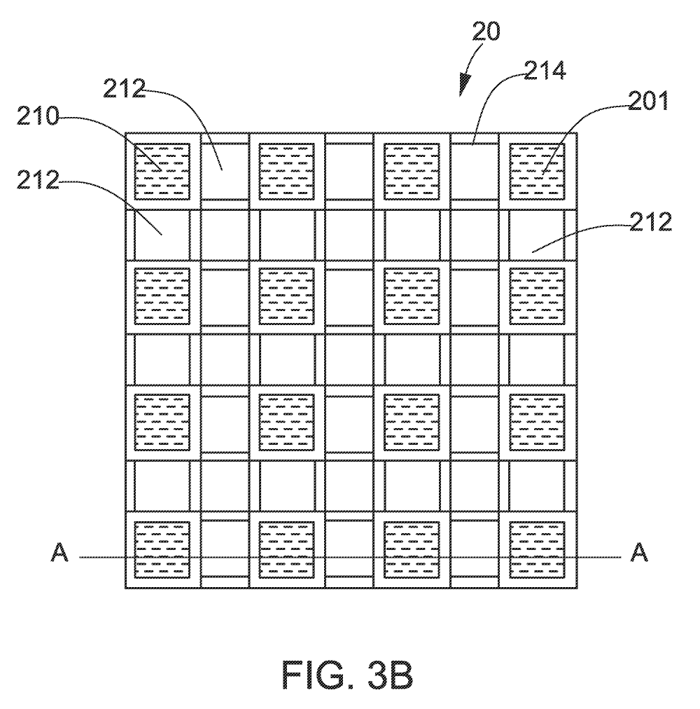

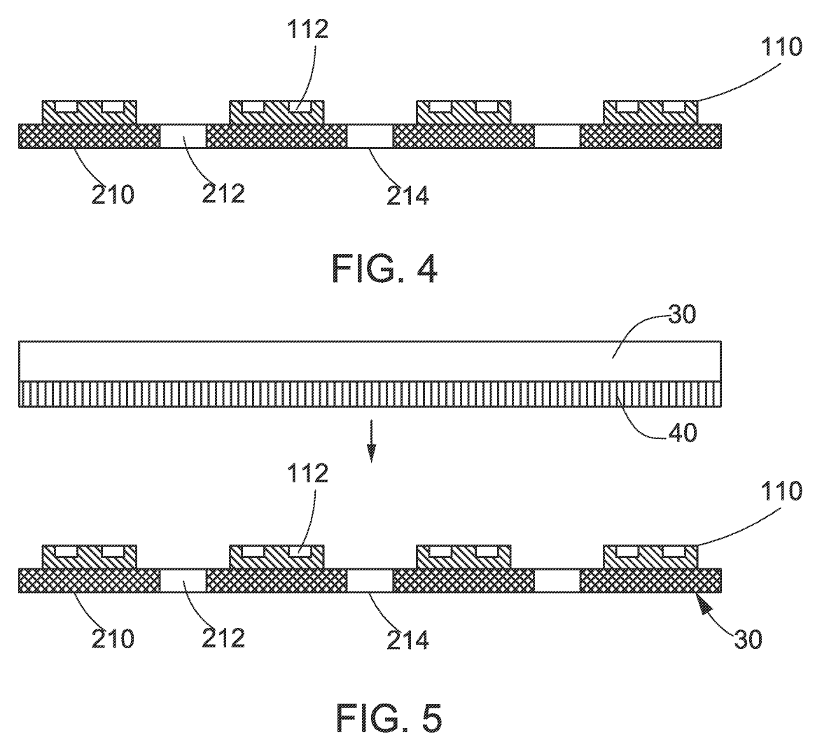

FIG. 3A and FIG. 3B are views showing that a plurality of chips is placed on the chip-placed area of the chip-placed frame. As shown in FIG. 3A and FIG. 3B, the wafer 10 is cut into a plurality of dice 110 and the active surface of each of the dice 110 is faced up. Then, a mechanical arm (not shown) is used to take up each dice and put it on the chip-placed area 210 of the chip-placed frame 20. Because there are a plurality of pads 112 disposed on the active surface of each of the dice and the mechanical arm can recognize the location of the pads 112 on the active surface of the chip 110. When the mechanical arm is going to put the chip 110 on the chip-placed area 210 of the chip-placed frame 20, the chip 110 is able to exactly put on the chip-placed area 210 of the chip-placed frame 20 in accordance with the reference point (not shown) of the chip-placed area 210 and the relative location of the chip-placed frame 20. Therefore, when the dice 110 are relocated on the chip-placed frame 20, the dice 110 are able to put on the current location of the chip-placed frame 20. Besides, the relative location of the chip-placed area 210 is used to enhance the accuracy of the relation of the dice 210 by using the chip-placed area 210 to relocate those dice 110. As shown in FIG. 4, it is a view according to the AA line segment in FIG. 3A and FIG. 3B and showing that the reverse surface of the dice 110 is put on the chip-placed area 210 of the chip-placed frame 20.

Besides, in the present embodiment, the chip-placed frame 20 further includes an adherent layer (not shown) and the adherent layer is used to stick the reverse surface of the chip 110 on the chip-placed area 210 when the chip 110 is put on the chip-placed areas 210 of the chip-placed frame 20. The material of the adhesive layer is a sticky material with elasticity and is selected form the group consisting of: silicone rubber, silicone resin, elasticity PU, multi-holes PU, acrylic rubber and chip cutting glue.

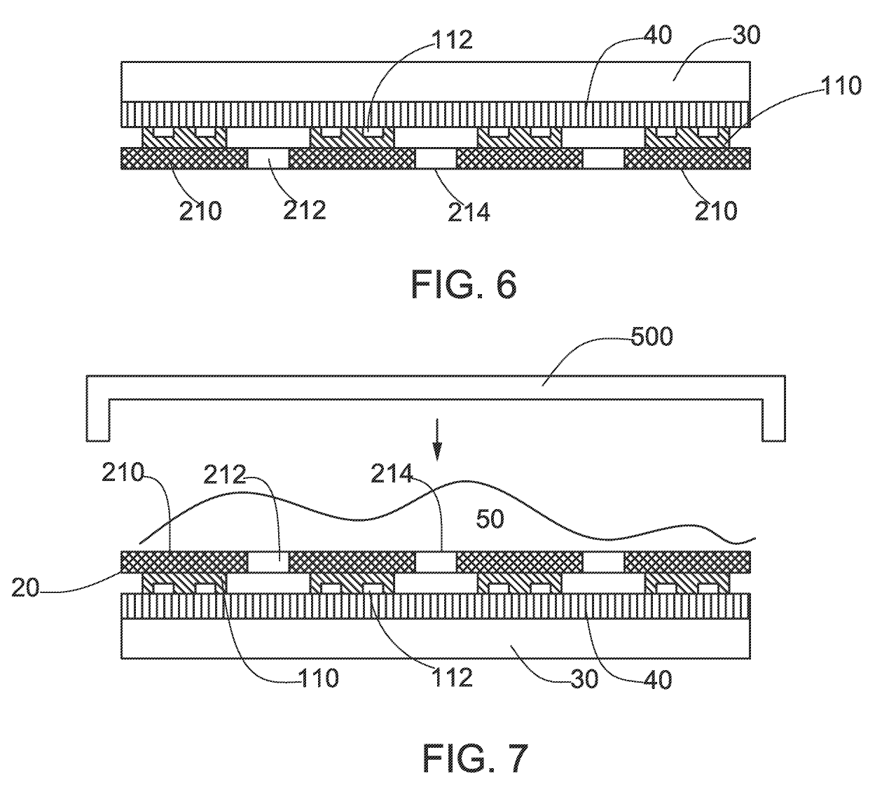

Now referring to FIG. 5 and FIG. 6, those are views showing that a carrier board with an adherent layer is glued on the active surface of each of the dice. As shown in FIG. 5, an adherent layer 40 is used to glue on a surface of a carrier board 30. Then, as shown in FIG. 5, the surface with the adhesive layer 40 is faced up and put on the active surface of the dice 110 of the chip-placed frame 20. The adhesive layer is used to glue on the active surface of each of the dice 110. In this embodiment, the adhesive layer 40 is selected from the group consisting of: silicone rubber, silicone resin, elasticity PU, multi-holes PU, acrylic rubber and chip cutting glue.

Now, it is trying to reverse the construction shown in FIG. 6. The sequence of the structure in FIG. 6 is the chip-placed areas 210 of the chip-placed frame 20, the dice 110 with the active surface being faced down, the adhesive layer 40 and the carrier board 30. As shown in FIG. 7, a polymer material 50 is injected into the chip-placed frame 20 and the active surface of a few of dice 110. The polymer 50 is flowed into the surrounding of the chip-placed area 210 of the chip-placed frame 20 by passing the gaps of the chip-placed frame 20 and injecting into the adherent layer 40. Then, a mold device 500 is used to flat off the polymer material 50 and the polymer material 50 on the chip-placed frame 20 is formed a flat surface. The polymer material 50 encapsulates the chip-placed frame 20 and every dices 110 and is filled between the dices 110 to form an encapsulated body. In the present embodiment, the polymer is silicone rubber, silicone resin, acrylic rubber, BCB and so on.

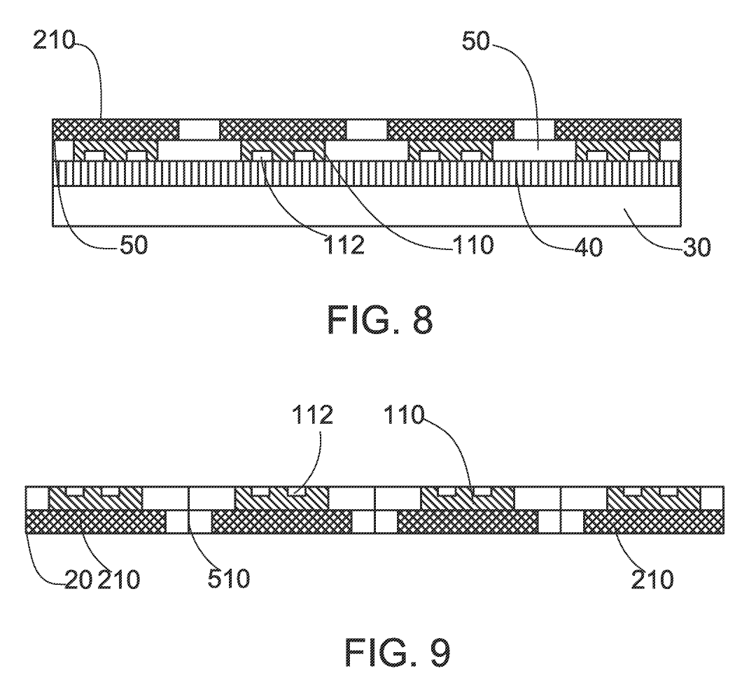

The flat polymer material 50 is able to perform a baking process to solid the polymers. And then, a mold-release process is used to separate the mold device 500 and the polymer 500 and expose the surface of the polymer material 50, as shown in FIG. 8. Next, the adherent layer 40 and the carrier board 30 are released from the active surface of the dice 110. The released method is to put the polymer material 50 and the carrier board 30 with the adhesive layer 40 in an ion basin (not shown) and the polymer material 50 and the carrier board 30 with the adhesive layer 40 is able to separate from each other. Therefore, an encapsulated body is formed and the structure is up side down to form a structure as shown in FIG. 9. The encapsulated body covers four sides of each of the dice 110 and exposes the pads 112 on the active surface of each of the dice 110. Because the encapsulated body on the active surface of the dice 110 includes a plurality of sawing lines 510, the stress of the encapsulated body will be released due to these sawing lines 510 when the polymer material 50 and the carrier board 30 are released. Next, a sawing knife is optionally utilized to saw the surface of the polymer material 50 to be a plurality of sawing lines. The depth of each of the sawing lines 510 is about 0.5˜1 mils. The width of each of the sawing lines 510 is about 5˜25 mm. In a preferred embodiment, the sawing lines 510 are interlaced to each other and used to be the reference line when sawing the dice.

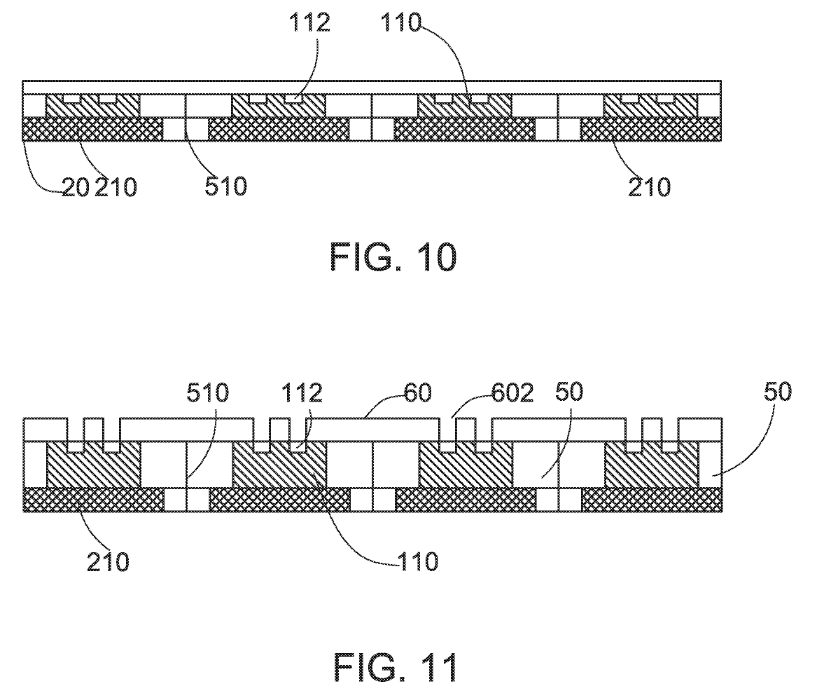

Now please referring to FIG. 10, the patterned first protective layer 60 is used to cover the active surface of each of the dice 110 and a portion of the surface of the polymer material 50. Therefore, the pads on the active surface of the dice 110 are able to be exposed. The steps to form the first protective layer 60 are described in the following paragraph. First, the first protective layer (not shown) is formed on the pads 112 of the active surface of each of the dice 110. Then a semiconductor process is used to form a patterned photoresist layer on the first protective layer. Next, an etching process is used to remove a portion of the first protective layer and then a patterned first protective layer 60 is formed on the active surface of the dice 110 and the pads 112 are exposed on the active surface of the dice 110, as shown in FIG. 11. The material of the first protective layer is paste or B-stage.

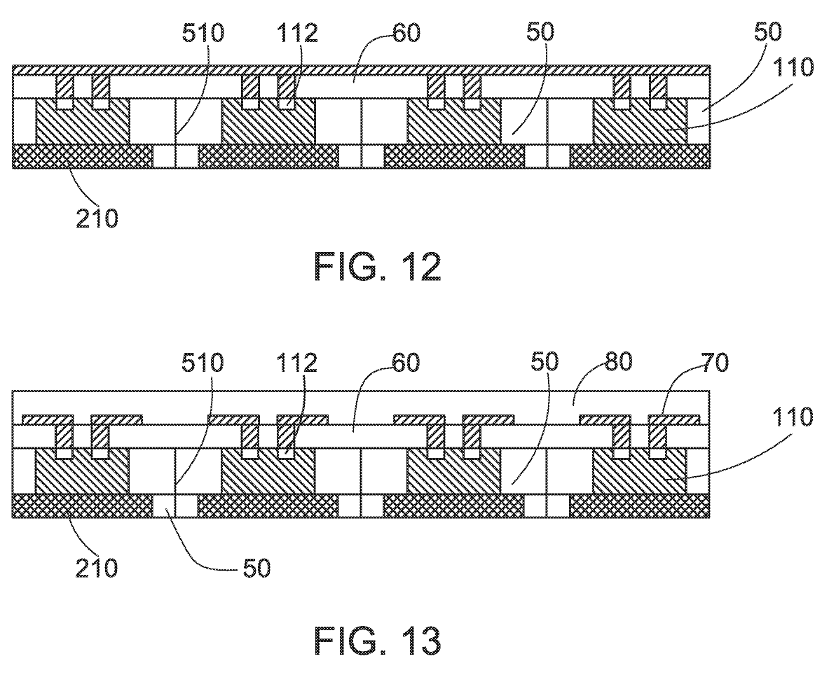

After the location of the pad 112 for each of the dice 110 is confirmed, the conventional redistribution layer (RDL) process is used on the pads 112 exposed on each of the dice 110 to form a plurality of fan-out and patterned metal traces 70. One end of ach of the patterned metal traces 70 is electrically connected to the pads 112 and some other ends of a portion of the patterned metal traces 70 are formed on the patterned first protective layer 60 by a fan-out format. The steps to form the patterned metal traces 70 include: forming a metal layer (not shown) on the patterned first protective layer 60 and the metal layer is filled into the exposed pads 112; forming a patterned photoresist payer (not shown) on the metal layer; etching a portion of the metal layer to form the patterned metal traces 70 and one end of each of some patterned metal traces is electrically connected to the pads on the active surface of the dice 110 and other end of each of some patterned metal traces 70 is electrically connected to the pads 112, as shown in FIG. 12.

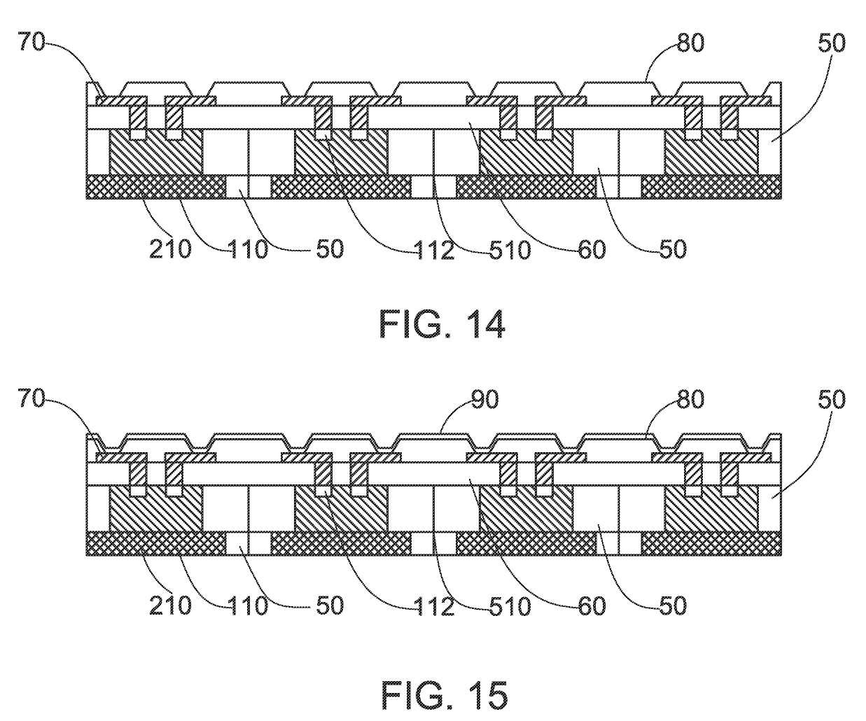

Now referring to FIG. 12, a second protective layer 80 is formed on the fan-out and patterned metal traces 70 and used to cover the active surface of each of the dice 110 and the fan-out and patterned metal traces 70 by a semiconductor manufacture, as shown in FIG. 13. Then, the same semiconductor manufacture is used to form a plurality of openings (not shown) on the second protective layer 80 and the externally extended surface of the active surface of each of the dice 110, which is opposite to the patterned metal traces 70. The steps of forming the openings on the second protective layer include: forming a patterned photoresist layer (not shown) above the second protective layer by a semiconductor manufacture, such as photo-lithography or etching; then etching to remove a portion of the second protective layer 80 to form a patterned second protective layer 80; exposing a surface of the other end of the fan-out and patterned metal trace 70, as shown in FIG. 14. The material of the second protective layer is paste or B-stage.

Now, in FIG. 15, it is a view showing that a plurality of patterned UBM layers are formed on the surface of the other end of the exposed, fan-out and patterned metal trace. As shown in FIG. 15, on the surface of the other end of the exposed, fan-out and patterned metal trace, a UBM layer (not shown) is formed by the way of sputtering. Next, by a semiconductor manufacture (such as photo-lithography or etching), a patterned photoresist layer (not shown) is formed on the UBM layer. Then, a portion of the UBM layer is removed by an etching method to form a plurality of patterned UBM layers 90 on the surface of the exposed each of the fan-out patterned metal traces. The patterned UBM layers 90 are electrically connected to the patterned metal traces 70, in the present embodiment, the material of the UBM layer 90 is Ti/Ni.

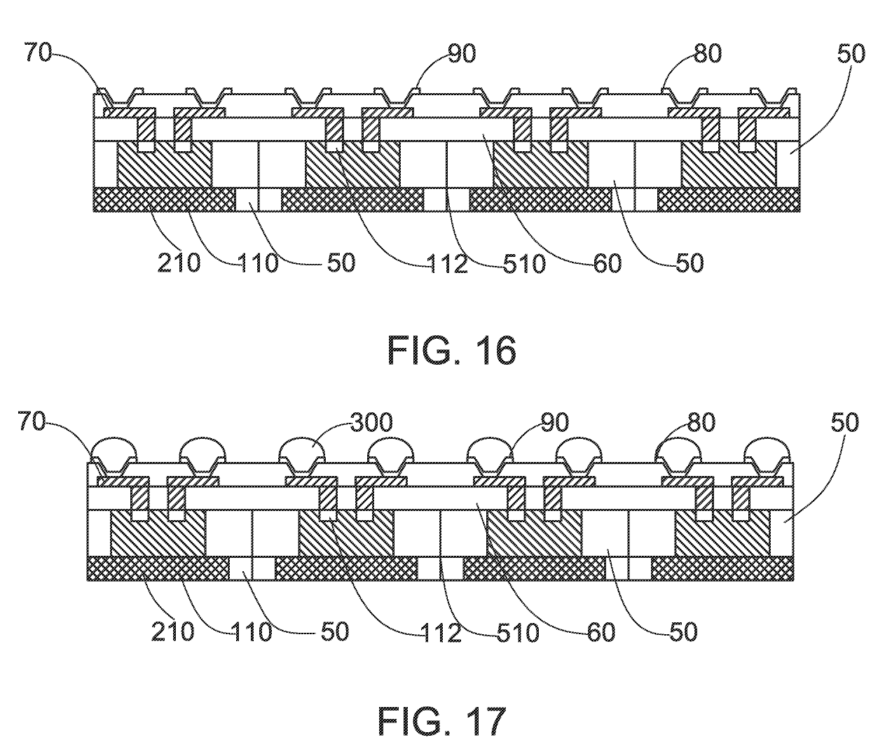

Now, in FIG. 16, a photo-lithography or etching method is used to remove a portion of the UBM layers 90 and keep some metal traces 70, which are electrically connected to the UBM layer 90.

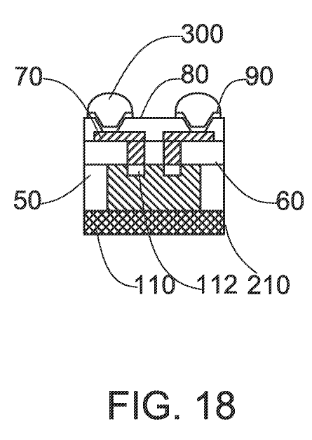

Eventually, a plurality of conductive elements 300 are formed on each of the UBM layers 90 and used to be the connective points for the dice 110 to connect the external components. The conductive elements 300 can be some metal bumps or solder balls and are electrically connected by the patterned UBM layers 90 and the patterned metal traces 70. Therefore, the package structure is able to perform the final cutting. In the present embodiment, the cutting unit can be a plurality of dice and formed a multi-dice package structure, as shown in FIG. 17. Besides, in a different embodiment, the cutting unit can be a chip and formed a single chip package structure, as shown in FIG. 18.

It should be noted that the fan-out structure of the metal trace 80 is not limited by using a conventional RDL and as long as the semiconductor manufacture method can form a fan-out structure can be one of the embodiments in the present invention. Basically, the semiconductor manufacture method to form a fan-out structure is a conventional prior art, the detail description is omitted herein.

In the embodiments described above, the flat polymer material 50 is formed by molding process. Moreover, a molding device 500 is sued to cover over the chip-placed frame 20 and keep a space between the molding device 500 and the dice 100, and then a molding process is used to put the polymer material 50, such as Epoxy molding compound (EMC), in the space between the molding device 500 and the dice 110. Therefore, the polymer material 50 is formed a flat surface. The polymer 50 is able to cover each of the dice 100 and filled in the gaps between the dice 100, and covered the chip-placed frame 20. Because the steps after the process are described in the previous sections, the detail description is omitted herein.

What is claimed is:

1. A die rearrangement package method, comprising:
providing a chip-placed frame, which includes a plurality of chip-placed areas, and a plurality of leads is used to connect each of said chip-placed areas and there is a gap existed between each said plurality of chip-placed areas;
providing a wafer, and said wafer includes a top surface and a reverse surface and said wafer includes a plurality of chips and each said plurality of chips includes an active surface and there are a plurality of pads disposed on said active surface;
sawing said wafer to become said plurality of chips;
pick and placing said plurality of chips on each said plurality of chip-placed areas and a reverse surface of each said plurality of chips is stuck on each said plurality of chip-placed areas;
sticking a carrier board with an adhesive layer on said active surface of each said plurality of chips;
injecting a polymer and said polymer is disposed on a surface of said chip-placed area, and said polymer material is filled into said gaps and covering each said plurality of chips to form a package structure;
removing said adhesive layer and said carrier board to expose said active surface of each said plurality of chips;
forming a plurality of patterned first protective layers on said chips and exposing said pads on said active surface of each said plurality of said chips;
forming a plurality of fan-out and patterned metal traces, and each of said patterned metal traces is electrically connected to said plurality of pads on said active surface of each said plurality of chips, and each of said patterned metal traces includes a fan-out structure, which is extended out of said active surface of each said plurality of chips;
forming a patterned second protective layer to cover said patterned metal trace and expose a portion of said fan-out structure, which is extended out of said active surface of each said plurality of chips;
forming a plurality of patterned UBM layers to cover a portion of said fan-out structure, which is extended out of said active surface of said chips, and said patterned UBM layer is electrically connected to said patterned metal traces;
forming a plurality of conductive elements, and said conductive elements are electrically connected to patterned metal traces by said patterned UBM layer; and
sawing said package structure and said leads of said chip-placed frame to form a plurality of stand alone and packaged chips.

2. The package method of claim 1, wherein said chip-placed areas is arranged by a square-shape.

3. The package method of claim 1, wherein said chip-placed areas is made by an etching method.

4. The package method of claim 1, wherein said leads are crisscrossedly connected to said plurality of chip-placed areas.

5. The package method of claim 1, wherein said step of forming said patterned metal traces comprises:
forming a metal layer to cover said plurality of pads of said active surface of each said plurality of chips and said polymer material;
forming a patterned photoresist layer on said metal layer; and
removing a portion of said metal layer to get rid of said metal layer on said active surface of said plurality of chips and forming said patterned metal traces, wherein one end of a portion of said patterned metal traces is electrically connected to said plurality of pads of said active surface of said plurality of chips, and one another end of a portion of said patterned metal traces is formed a fan-out structure on said polymer material.

6. A die module rearrangement method, comprising:
providing a chip-placed frame, which includes a plurality of chip-placed areas, and a plurality of leads are used to connect each said plurality of chip-placed areas and there is a gap existed between said plurality of chip-placed areas;
providing a wafer, and said wafer includes a top surface and a reverse surface and said wafer includes a plurality of chips and each said plurality of chips includes an active surface and there is a plurality of pads disposed on said active surface;
sawing said wafer to become said plurality of chips;
pick and placing said plurality of chips on each said plurality of chip-placed areas and a reverse surface of each said plurality of chips is stuck on each said plurality of chip-placed areas;
sticking a carrier board with an adhesive layer on said active surface;
injecting a polymer material and said polymer material is disposed on a surface of said plurality of chip-placed areas, and said polymer material is filled into said gaps and covering each said plurality of chip-placed frames to form a package structure;
removing said adhesive layer and said carrier board to expose said active surface of each said plurality of chips;
forming a plurality of patterned first protective layers on said plurality of chips and exposing said plurality of pads on said active surface of each said plurality of chips;
forming a plurality of fan-out and patterned metal traces, and each of said patterned metal traces is electrically connected to said plurality of pads on said active surface of each said plurality of chips, and each of said patterned metal traces includes a fan-out structure, which is extended out of said active surface of said plurality of chips and said plurality of fan-out structure covers on a portion of said patterned first protective layer;
forming a patterned second protective layer to cover said patterned metal traces and expose a portion of said patterned fan-out structure, which is extended out of said active surface of said plurality of chips;
forming a plurality of patterned UBM layers to cover a portion of said fan-out structure, which is extended out of said active surface of said plurality of chips, and said patterned UBM layer is electrically connected to said patterned metal traces;
forming a plurality of conductive elements, and said plurality of conductive elements are electrically connected to said patterned metal traces by said patterned UBM layer; and
sawing said package structure and said leads of said chip-placed frame to form a plurality of stand alone and packaged chips.

7. The package method of claim 6, wherein said plurality of chip-placed areas are arranged by a square-shape.

8. The package method of claim 6, wherein said leads are crisscrossedly connected to the chip-placed areas.

9. The package method of claim 6, wherein said chip-placed areas are made by an etching method.

10. The package method of claim 6, wherein said step of forming said patterned metal traces comprises:
forming a metal layer to cover said plurality of pads of said active surface and said polymer material;
forming a patterned photoresist layer on said metal layer; and
removing a portion of said metal layer to get rid of said metal layer on said active surface of said plurality of chips and forming said patterned metal traces, wherein one end of a portion of said patterned metal traces is electrically connected to said pads of said active surface of said plurality of chips, and one another end of a portion of said patterned metal traces is formed a fan-out structure on said polymer material.

11. The package method of claim 10, wherein the material of said UBM layer is Ti/Ni.

12. The package method of claim 10, wherein said conductive elements is solder balls.

13. The package method of claim 10, wherein said conductive elements is solder bumps.

14. A die rearrangement package structure, comprising:
a chip-placed frame, which includes a chip-placed area, and a top surface of said chip-placed area includes an adhesive layer;
a chip including an active layer and a reverse surface, and said active layer includes a plurality of pads and said reverse surface is formed on said adhesive layer of said chip-placed area;
a package structure surrounding said chip-placed frame and said chip and said plurality of pads on active surface are exposed;
a plurality of patterned first protective layer used to cover said active surface of said chip and exposed said plurality of pads on said chip;
a plurality of patterned metal traces, and one end of said patterned metal trace is electrically connected to said plurality of pads and one another end of said patterned metal trace is extended and covered a surface of said patterned first protective layer;
a plurality of second protective layer used to cover said patterned metal traces and expose a portion of a surface of a fan-out structure of said patterned metal traces, which is extended out of said active surface;
a plurality of patterned UBM layer formed on said fan-out structure and electrically connected to said patterned metal traces; and
a plurality of conductive elements formed on said patterned UBM layer and electrically connected to said patterned metal traces by said patterned UBM layer.

15. The package structure of claim 14, wherein said conductive elements is solder balls.

16. The package structure of claim 14, wherein said conductive elements is solder bumps.

17. A die module rearrangement package structure, comprising:
a chip-placed frame, which includes a plurality of chip-placed areas, and a top surface of said chip-placed area includes an adhesive layer;
a chip including an active layer and a reverse surface, and said active layer includes a plurality of pads and said reverse surface is formed on said adhesive layer of said chip-placed area;
a package structure surrounding said chip-placed frame and said chip and said plurality of pads on active surface are exposed;
a plurality of patterned first protective layer used to cover said active surface of said chip and exposed said plurality of pads on said chip;
a plurality of patterned metal traces, and one end of said patterned metal trace is electrically connected to said plurality of pads and one another end of said patterned metal trace is extended and covered a surface of said patterned first protective layer;
a plurality of second protective layers used to cover said patterned metal traces and expose a portion of a surface of a fan-out structure of said patterned metal traces, which is extended out of said active surface;
a plurality of patterned UBM layers formed on said fan-out structure and electrically connected to said patterned metal traces; and
a plurality of conductive elements formed on said patterned UBM layer and electrically connected to said patterned metal traces by said patterned UBM layer.

18. The package structure of claim 17, wherein the material of said chip-placed frame is metal.

19. The package structure of claim 17, wherein said chip-placed areas are arranged by a square-shape.

20. The package structure of claim 17, wherein said leads are crisscrossedly connected to the chip-placed areas.
